(19) United States
(12) Patent Application Publication
(10) Pub. No.: US 2010/0167480 A1
(43) Pub. Date: Jul. 1, 2010

(54) Method for Manufacturing Flash Memory Device

(76) Inventor: Seung Kwan PAEK, Seoul (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/623,729

(22) Filed: Nov. 23, 2009

(30) Foreign Application Priority Data
Dec. 31, 2008 (KR) 10-2008-0137769

(51) Int. Cl. H01L 21/336

(52) U.S. Cl. 438/261; 257/E21.422

(57) ABSTRACT

The present invention relates to a method for fabricating a flash memory device capable of reducing charge loss. The method includes forming a gate pattern on a semiconductor substrate, forming a sidewall spacer layer on the gate pattern using SiO₂, introducing nitrogen into the sidewall spacer layer to form a SiON film, and forming a capping film over the entire SiON film.

### CROSS REFERENCE TO RELATED APPLICATION

This application claims the benefit of Korean Patent Application No. 10-2008-0137769, filed on Dec. 31, 2008 which is hereby incorporated by reference as if fully set forth herein.

### BACKGROUND OF THE INVENTION

1. Field of the Invention

The present invention relates to a method for manufacturing a flash memory device and, more particularly, a method for manufacturing a flash memory device capable of reducing charge loss.

2. Discussion of the Related Art

It is generally known that a flash memory device is a programmable ROM (“PROM”) for writing, deleting, and reading information from memory cells.

Such a flash memory device may be classified into a NOR type structure wherein cells are aligned in parallel between a bit line and a ground and a NAND type structure wherein cells are aligned in series between the bit line and the ground, based on a chosen cell array system.

A NOR type flash memory device enables implementation of high speed random access during reading, and can be used to boot up a cell phone. A NAND type flash memory device having lower reading speed but higher writing speed is suitable for data storage and is advantageous for device miniaturization.

The category of flash memory devices may be divided into a stack gate type device and a split gate type device according to a chosen construction of a unit cell, and may further be sorted into devices having different charge storage mode (e.g., floating gate devices and a silicon-oxide-nitride-oxide-silicon (“SONOS”) devices). In particular, floating gate devices generally include a floating gate comprising polycrystalline silicon surrounded by insulating material wherein charge is injected into or emitted from the floating gate by hot carrier injection or Fowler-Nordheim (“F—N”) tunneling, to store or delete data.

The floating memory device has, in general, a floating gate and a control gate, wherein the floating gate serves as a chamber (or storage) for storing charge.

However, with a continuing trend towards decreasing the size of flash memory devices, reductions in floating gate device size entails problems of charge loss and charge gain.

### SUMMARY OF THE INVENTION

Accordingly, the present invention is directed to solving the foregoing problems in regard to conventional techniques, and an object of the present invention is to provide a method for manufacturing a flash memory device capable of reducing charge loss.

Additional advantages, objects, and features of the invention will be set forth in part in the description which follows and will become apparent to those skilled in the art upon examination of the following description or may be learned from practice of the invention. The objectives and other advantages of the invention may be realized and attained by the structure particularly pointed out in the written description and claims hereof as well as the appended drawings.

According to an exemplary embodiment, the present invention relates to a process for manufacturing a flash memory device, including: forming a gate pattern on a semiconductor substrate; forming a sidewall spacer layer on the gate pattern comprising SiO₂; introducing nitrogen into the sidewall spacer layer to form a SiON film; and forming a capping film over the entirety of the SiON film.

As described above, according to the inventive method for manufacturing a flash memory device, a sidewall spacer layer comprising SiON functions as a barrier to prevent migration of electrons and thereby reduces charge loss, and neutralizes dangling bonds at an interface of the sidewall spacer layer and the gate pattern to thereby decrease charge trapping, which in turn improves charge gain. In addition, the SiON material of the sidewall spacer layer is resistant to photoresist etching, stripping, and/or removal of photoresist residues, and thus partial etching of the sidewall spacer layer can be prevented. As a result, the charge retention of the flash memory device may be improved.

### BRIEF DESCRIPTION OF THE DRAWINGS

The accompanying drawings, which are included to provide a further understanding of the invention and are part of this application, illustrate embodiment(s) of the invention and together with the description serve to explain the principle of the invention. In the drawings:

FIGS. 1A to 1D are cross-sectional views illustrating a process for manufacturing a flash memory device according to the present invention.

### DETAILED DESCRIPTION OF THE INVENTION

Hereinafter, the foregoing object and characteristics of the present invention will be described in detail by the following description with reference to exemplary embodiments, in conjunction with the accompanying drawings. The following detailed description is intended to explain technical aspects and functional effects of the present invention by example with reference to the accompanying drawings. However, technical concepts, design features, and effects of the present invention are not limited to the examples provided herein.

Hereinafter, an exemplary method for manufacturing a flash memory device according to the present invention is described in detail and in reference to the accompanying drawings.

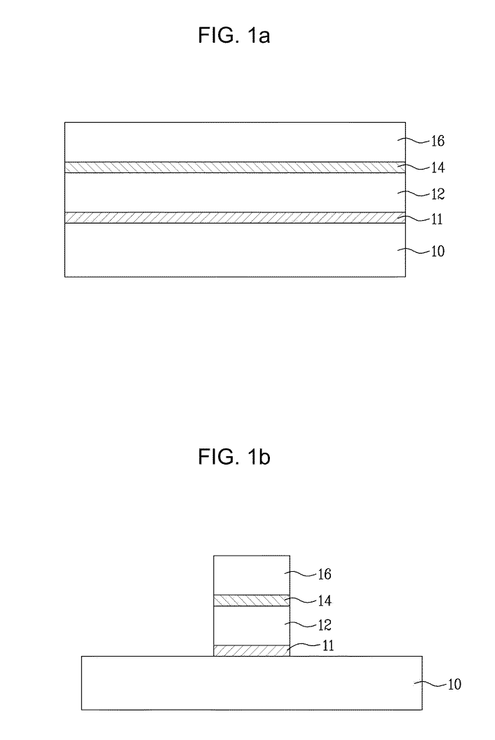

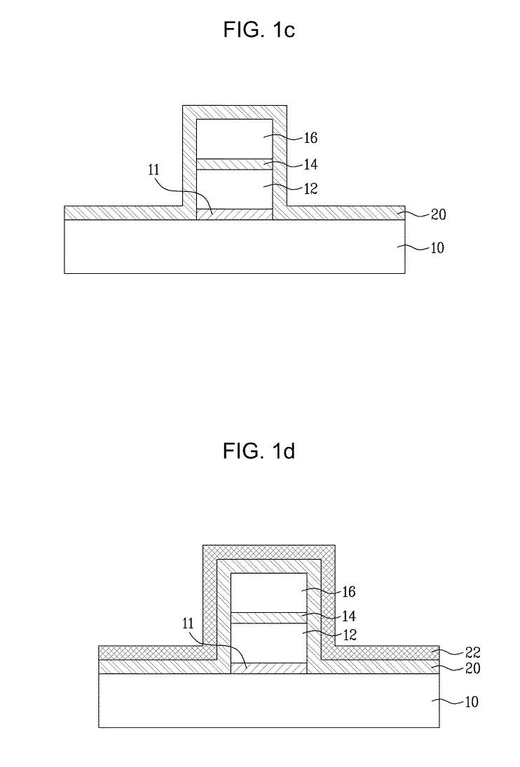

FIGS. 1A to 1D are cross-sectional views illustrating a process for manufacturing a flash memory device according to the present invention.

Referring to FIG. 1A, a plurality of device isolation layers (not shown) spaced from one another at constant intervals are formed in a semiconductor substrate 10 (which may be a single-crystal silicon wafer, or a single-crystal silicon wafer with one or more layers of epitaxial silicon grown thereon) in order to define an active region and a device isolation region. In addition, a well (not shown) is formed in the active region of the semiconductor substrate 10 by forming a photoresist mask defining the well, and implanting impurity ions into the semiconductor substrate 10 through the photoresist mask. For instance, for a first conductive type (e.g., P-type) substrate, a second conductive type (e.g., N-type) deep well is formed, followed by forming a second photoresist mask defining one or more pocket well regions and implanting a first conductive type (e.g., P-type) impurity to form a pocket well (not shown). Then, a cell threshold voltage is adjusted by implanting first conductive type (e.g., P-type) impurity ions in a threshold voltage implant process. The example given above is not intended to limit the present invention, and the first and second conductive types may be reversed within the scope of the present invention.

Although not illustrated in FIGS. 1A-1D, a process for fabricating each device isolation layer comprises: sequentially forming a pad oxide film (e.g., by wet or dry thermal oxidation of the substrate, or by chemical vapor deposition [CVD]), forming a nitride film (e.g., by physical vapor deposition [PVD] such as sputtering, or by CVD), and forming an oxide film (e.g., by CVD such as high density plasma [HDP] CVD) on the semiconductor substrate 10; and etching the stack of layers and the semiconductor substrate to a predetermined depth to form an isolation trench. Next, an isolation film is blanket deposited on the semiconductor substrate 10, including the trench by CVD using, for example, tetraethylorthosilicate (TEOS) or silane (e.g., SiH₄) as a silicon source and dioxygen (O₂) and/or ozone (O₃) as an oxygen source. The isolation film is then removed and/or planarized by chemical mechanical polishing (CMP) until an upper surface of the semiconductor substrate 10 is exposed, thereby forming the device isolation layers that define the active regions of the semiconductor substrate 10.

Subsequently, a tunnel oxide film 11 and a floating gate 12 are formed on the active region of the semiconductor substrate 10. The tunnel oxide film may be formed by wet or dry thermal oxidation of the semiconductor substrate 10 (e.g., at a temperature of 800˜1200° C.). The floating gate 12 may be formed by depositing a doped polysilicon layer. The doped polysilicon layer may be formed by low pressure CVD [LPCVD] or plasma enhanced CVD [PECVD] using silane (SiH₄) or disilane (Si₂H₆) and a dopant gas (e.g., a P-type dopant gas such as BCl₃, B₂H₆, or an N-type dopant gas such as PH₃). Alternatively, the floating gate 12 may be formed by depositing a undoped polysilicon layer by LPCVD or PECVD using silane (SiH₄) or disilane (Si₂H₆), and then implanting dopant ions (e.g., a P-type dopant such as B or BF₂, or an N-type dopant such as P, As, or Sb) into the undoped polysilicon layer.

Then, an oxide-nitride-oxide (“ONO”) film 14 and a control gate 16 are formed in sequential order over the floating gate 12. The ONO film 14 may be formed by depositing a first oxide by CVD (e.g., PECVD) of tetraethylorthosilicate (TEOS), then depositing a nitride film by PVD or CVD, and depositing a second oxide by CVD (e.g., PECVD) of TEOS. The control gate 16 may be formed by deposited a doped polysilicon layer by a process as described above with regard to forming the floating gate 12.

As shown in FIG. 1B, the tunnel oxide film 11, the floating gate 12, the ONO film 14, and the control gate 16 are patterned to form a gate pattern in the active area of the semiconductor substrate 10 having a desired width, leaving a predetermined distance between the gate pattern and the device isolation layers. It should be understood that, although FIGS. 1A-1D show a single active area, a flash memory device formed according to the present method will include multiple active regions and device isolation layers, generally arranged in an array. As a result of the patterning process, the patterned films (i.e., the tunnel oxide film 11, the floating gate 12, the ONO film 14, and the control gate 16) form a plurality of stacks (e.g., as shown in FIG. 1B) in a plurality of active areas. Hereinafter, the plurality stacks will be described in reference to the gate pattern shown in FIGS. 1B-1D.

As illustrated in FIG. 1C, a sidewall spacer layer 20 comprising a SiO₂ film is formed on the sidewalls and top of the gate pattern. A decoupled plasma nitridation (“DPN”) process is then performed to introduce nitrogen into the sidewall spacer layer 20 so as to form a silicon oxynitride (SiON) film. For example, the DPN process may comprise exposing the SiO₂ film of the sidewall spacer layer 20 to a plasma treatment with a nitrogen-containing reactive gas (e.g., N₂, NO, N₂O, NO₂, and/or NH₃) at a temperature of about 50˜200° C. for about 30 to 300 seconds, at a pressure of about 5 to 50 mTorr, and a power source of about 500 to 900 W. The DPN process may provide a greater amount of nitride to the sidewall spacer layer 20 than a conventional furnace nitridation to form a SiON film.

Accordingly, a thickness of the sidewall spacer layer 20 can be reduced in comparison to an equivalent conventional spacer comprising or consisting essentially of an oxide film. In addition, the sidewall spacer layer 20 comprising a SiON film serves as a barrier to prevent migration of electrons, which in turn reduces charge loss. The SiON film may also neutralize dangling bonds at an interface of the sidewall spacer layer 20 and the gate pattern to decrease charge trapping, which in turn improves charge gain.

Afterward, the resulting device may be subjected to an annealing process (e.g., rapid thermal annealing [RTA] at a temperature of about 800˜1000° C.). The annealing process may correct defects in the sidewall spacer 20 layer caused by the nitridation process.

Next, as illustrated in FIG. 1D, a capping film 22 is formed over the entirety of the sidewall spacer layer 20 using a high temperature oxide (“HTO”). Here, “HTO” means an oxide film prepared at a relatively high temperature, compared to other oxide films. For example, the HTO can be deposited by LPCVD of TEOS or a silane (e.g., SiH₄) as a silicon source and dioxygen (O₂) and/or ozone (O₃) as an oxygen source at a temperature of about 400˜600° C. The capping film 22 is favorably formed with a thickness ranging from 15 to 25 Å.

The capping film 22 formed above is effective to prevent partial etching of the sidewall spacer layer 20 that may be caused by subsequent photoresist etching, stripping, and/or removal of photoresist residues in later processing steps, e.g., a process for forming an LDD region. As a result, charge retention of the flash memory device may be improved. The improved charge retention of the device results in a higher pass rate in a data retention bake (“DRB”) test, indicating an enhancement in production yield.

The present invention is not limited to the foregoing exemplary embodiments, as shown in the accompanying drawings. It will be apparent to those skilled in the art that the present invention may cover equivalents, variations, and/or modifications of embodiments described herein without departing from the scope of the invention. Accordingly, a scope of the present invention is not restricted to the detailed description above.

What is claimed is:

1. A method for manufacturing a flash memory device, comprising:
forming a gate pattern on a semiconductor substrate;
forming a sidewall spacer layer on the gate pattern comprising SiO₂;
introducing nitrogen into the sidewall spacer layer to form a SiON film; and
forming a capping film over the entire SiON film.

2. The method according to claim 1, wherein introducing the nitrogen into the sidewall spacer layer comprises a decoupled plasma nitridation (DPN) process.

3. The method according to claim 1, wherein forming the capping film comprises depositing a high temperature oxide (HTO).

4. The method according to claim 1, further comprising annealing the sidewall spacer layer after introducing the nitrogen into the sidewall spacer layer.

5. The method according to claim 4, wherein the annealing comprises a rapid thermal annealing (RTA) process.

6. The method according to claim 1, wherein the gate pattern comprises a tunnel oxide film, a floating gate, an ONO film, and a control gate.

7. The method according to claim 1, wherein the sidewall spacer layer is formed on the sidewalls and a top of the gate pattern.

8. The method according to claim 1, wherein the capping film has a thickness ranging from 15 to 25 Å.

9. The method according to claim 1, wherein a source of the nitrogen in the introducing step comprises N₂, NO, N₂O, NO₂, and/or NH₃.

10. The method according to claim 9, wherein the nitrogen is introduced at a temperature of about 50˜200° C. for about 30 to 300 seconds, at a pressure of about 5 to 50 mTorr, and a power source of about 500 to 900 W

11. The method according to claim 3, wherein the high temperature oxide (HTO) comprises a tetraethylorthosilicate (TEOS)- or silane-based oxide.

12. The method according to claim 5, wherein the rapid thermal annealing (RTA) process is performed at a temperature of about 800˜1000° C.

13. The method according to claim 6, wherein the tunnel oxide film comprises a thermal oxide.

14. The method according to claim 13, wherein the floating gate and the control gate each comprise polysilicon.

15. The method according to claim 14, wherein the control gate comprises doped polysilicon.

16. The method according to claim 1, wherein the SiON film has a thickness ranging from 15 to 25 Å.

17. The method according to claim 1, further comprising anisotropically etching the capping film and the SiON film to form sidewall spacers.

18. The method according to claim 1, further comprising, before forming a sidewall spacer layer on the gate pattern, implanting N-type or P-type impurities into the substrate using the gate pattern as a mask to form lightly-doped source-drain extensions.

19. The method according to claim 17, further comprising, after anisotropically etching the capping film and the SiON film, implanting N-type or P-type impurities into the substrate using the gate pattern and the sidewall spacers as a mask to form source and drain terminals.
